(19) United States
(12) Patent Application Publication
(10) Pub. No.: US 2006/0290001 A1
(43) Pub. Date: Dec. 28, 2006

(54) Interconnect vias and associated methods of formation

(75) Inventor: Marc Sulfridge, Boise, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/169,546

(22) Filed: Jun. 28, 2005

(51) Int. Cl. H01L 23/48

(52) U.S. Cl. 257/774

(57) ABSTRACT

Interconnect vias and associated methods of formation are disclosed. One such method includes forming an operable microelectronic feature in a substrate, with the substrate having a first surface and a second surface facing away from the first surface. The method can further include forming a via in the substrate at a process temperature of less than 173K, with the via extending into the substrate from the first surface. A conductive material can be disposed in the via to be in electrical communication with a bond site of the substrate. The microelectronic feature can be coupled to the bond site. In other embodiments, the process can include controlling an angle of sidewalls of the via, and/or forming the via in a single, generally continuous process, in addition to, or in lieu of, forming the via at cryogenic temperatures.

### TECHNICAL FIELD

The present invention is directed generally toward interconnect vias and associated methods of formation, including, but not limited to methods for forming vias having smooth inner surfaces and/or controlled sidewall angles, e.g., using a continuous process.

### BACKGROUND

Microelectronic imagers are used in digital cameras, wireless devices with picture capabilities, and many other applications. Cell phones and Personal Digital Assistants (PDAs), for example, are incorporating microelectronic imagers for capturing and sending pictures. The growth rate of microelectronic imagers has been steadily increasing as they become smaller and produce better images with higher pixel counts.

Microelectronic imagers include image sensors that use Charged Coupled Device (CCD) systems, Complementary Metal-Oxide Semiconductor (CMOS) systems, or other solid-state systems. CCD image sensors have been widely used in digital cameras and other applications. CMOS image sensors are also quickly becoming very popular because they are expected to have low production costs, high yields, and small sizes. CMOS image sensors can provide these advantages because they are manufactured using technology and equipment developed for fabricating semiconductor devices. CMOS image sensors, as well as CCD image sensors, are accordingly “packaged” to protect their delicate components and to provide external electrical contacts.

FIG. 1A is a partially schematic illustration of an imaging device 10 configured in accordance with the prior art. The imaging device 10 includes a die 20 having an integrated circuit 21 coupled to an image sensor 12. A color filter array (CFA) 13 is formed over the active pixels of the image sensor 12. The CFA 13 has individual filters or filter elements configured to allow the wavelengths of light corresponding to selected colors (e.g., red, green, or blue) to pass to each pixel of the image sensor 12. A plurality of microlenses 14 form a microlens array 15 that is positioned over the CFA 13. The microlenses 14 are used to focus light onto the initial charge accumulation regions of the image sensor pixels. A glass cover 16 is positioned to protect the microlens array 1.5 and other features of the die 20 from contamination. A device lens 17 is positioned a selected distance from the microlens array 15 to focus light onto the microlens array 15 and ultimately onto the image sensor 112.

The integrated circuit 21 of the die 20 can be electrically coupled to external devices via solder balls 11. The solder balls 11 are located on the side of the die 20 opposite from the image sensor 12 so as to avoid interference with the operation of the image sensor 12. Accordingly, the die 20 can include multiple through-wafer interconnects (TWIs) connected between the solder balls 11 and the bond pads 22, which are in turn connected to the integrated circuit 21. Each TWI can include a via that extends through the die 20, and an electrically conductive interconnect structure 30 located in the via.

FIGS. 1B-1E schematically illustrate a technique, typically referred to as a Bosch process, for forming the via in the die 20. Beginning with FIG. 1B, a mask 25 is positioned over the upper surface of the die 20, with an opening aligned with the bond pad 22. A plasma, typically an inductively coupled plasma, is introduced into a chamber in which the die 20 is positioned to initiate the formation of a via 23 that is axially aligned with an aperture formed in the bond pad 22. The via includes a generally cylindrical sidewall 24 that has a barrel-type shape (exaggerated in FIG. 1B for purposes of illustration). After an initial portion of the via is formed in the die 20, a dielectric layer 31 is formed on the sidewall 24 (as shown in FIG. 1C) to passivate the initially formed portion of the sidewall 24. Accordingly, the dielectric layer 31 can prevent the initially formed sidewall portion from becoming further widened as the via is deepened.

FIG. 1D illustrates a subsequent step in which the via is further extended into the die 20, and after which the dielectric layer 31 is again applied to coat the newly formed sidewall portion. As shown in FIG. 1E, the process is repeated until the via extends to a desired depth beneath the surface of the die 20. The via is then filled with a conductive material 32 and the back surface of the die 20 is ground to expose the conductive material opposite the bond pad 22. The solder ball 11 is then attached to the conductive material 32 to provide electrical communication between the bond pad 22 and external devices.

One characteristic of the via 23 shown in FIGS. 1B-1E is that it has a scalloped sidewall surface, a result of the intermittent material removal process and intermittent dielectric layer deposition process. A drawback associated with the scalloped sidewall shape is that it can create sharp points 28 in both the sidewall contour and in the dielectric layer 31. Each of these points can become a source for stress concentrations which can cause cracks to propagate not only in the dielectric layer 31, but also in the conductive material 32. These cracks can degrade the performance and/or reliability of the device and in some cases, can cause an open circuit between the solder ball 11 and the bond pad 22, causing the device to be inoperative.

Another characteristic is that the via 23 can have an overall barrel-type shape, as is shown in FIG. 1E. The overall barrel shape of the via 23 can cause shadowing affects. For example, the overhanging or upper portion of the via 23 can shadow regions below, causing a reduced uniformity with which the dielectric layer 31 and/or the conductive material 32 are formed in the via 23. These non-uniformities can also lead to a failure of the device in which the via 23 is formed. Accordingly, there is a need for an improved process for forming the through-wafer interconnects in the die 20.

### BRIEF DESCRIPTION OF THE DRAWINGS

FIGS. 1A-1E illustrate an imaging device formed by a process in accordance with the prior art.

FIG. 2 is a flow diagram illustrating a process for forming vias and conductive structures in accordance with several embodiments of the invention.

FIG. 3A is a partially schematic, cross-sectional illustration of a substrate prior to having a via formed in accordance with an embodiment of the invention.

FIGS. 3B-3E illustrate a process for forming a via in accordance with an embodiment of the invention.

FIGS. 4A-4K illustrate a process for disposing a conductive material in the via in accordance with an embodiment of the invention.

FIG. 5 illustrates an imaging device that includes through-wafer interconnects configured in accordance with an embodiment of the invention.

### DETAILED DESCRIPTION

A. Overview/Summary

The following disclosure describes several embodiments of methods for forming through-wafer interconnects, and devices formed using such techniques. One such device includes a substrate having a first surface, a second surface facing away from the first surface, and an interconnect via extending between the first and second surfaces. The interconnect via can have a smooth, continuous inner surface. An operable microelectronic feature is carried by the substrate, and a conductive interconnect structure is positioned in the interconnect via so as to extend from the first surface to the second surface of the substrate. The interconnect structure can have a first bond site at the first surface coupled to the microelectronic feature, and a second bond site at the second surface. An outer surface of the interconnect structure adjacent to the inner surface of the via can be smooth and continuous. In particular embodiments, the surfaces of the interconnect via and the interconnect structure can taper inwardly from the first surface to the second surface in a generally continuous manner. The operable microelectronic feature of the device can include at least one of a conductive line, an image sensor, and a capacitor.

A method for forming a microelectronic device in accordance with another embodiment of the invention includes forming an operable microelectronic feature in a substrate having a first surface and a second surface facing away from the first surface. The method can further include forming a via in the substrate at a process temperature of less than about 173K. The via can extend into the substrate from the first surface. The method can further include disposing a conductive material in the via, with the conductive material being an electrical communication with a bond site positioned at the first surface of the substrate. The method can further include coupling the microelectronic feature to the bond site.

In other embodiments, methods for forming the microelectronic device can include other features in addition to or in lieu of forming the via at a process temperature of less than 173K. For example, in one embodiment, the process can include controlling an angle of the via sidewalls relative to an axis extending through the via generally normal to the first and second surfaces of the substrate. Controlling the angle can include controlling a temperature and/or an oxygen concentration of an environment in which the via is formed. In another embodiment, removing material from the substrate to form the via can be completed in a single, generally continuous process. In particular embodiments, the process can also be completed at cryogenic temperatures, for example, temperatures less than 173K.

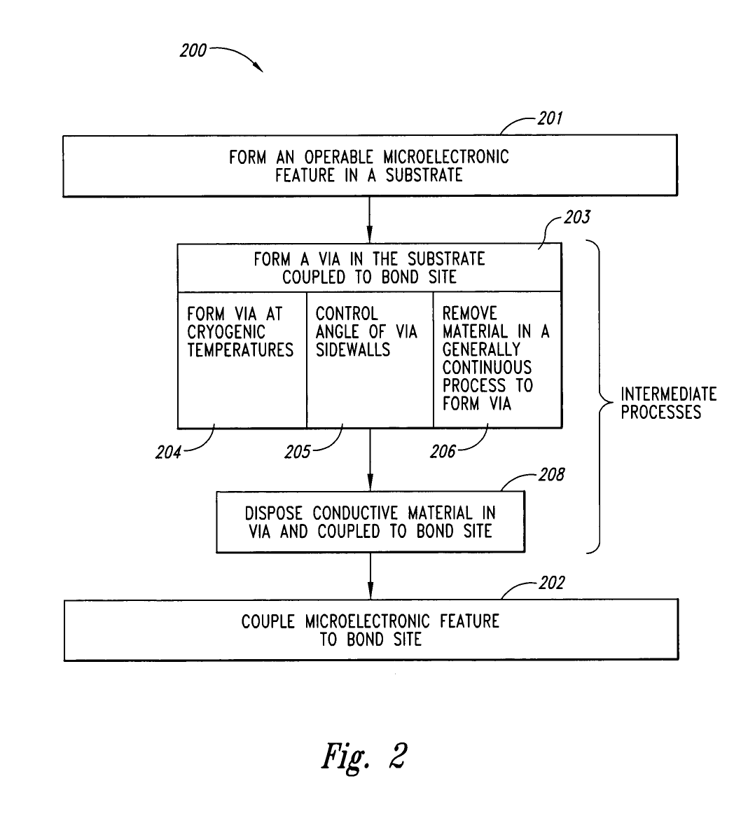

Specific details of several embodiments of the invention are described below with reference to CMOS image sensors to provide a thorough understanding of these embodiments, but other embodiments can use CCD image sensors or other types of solid-state imaging devices. In other embodiments, the invention can be practiced in connection with devices that do not include image sensors. Several details describing structures or processes that are well-known and often associated with other types of microelectronic devices are not set forth in the following description for purposes of brevity. Moreover, although the following disclosure sets forth several embodiments of different aspects of the invention, several other embodiments of the invention can have different configurations or different components than those described in this section. As such, the invention may have other embodiments with additional elements or without several of the elements described below with reference to FIGS. 2-5.

B. Methods for Forming Interconnect Vias and Conductive Structures

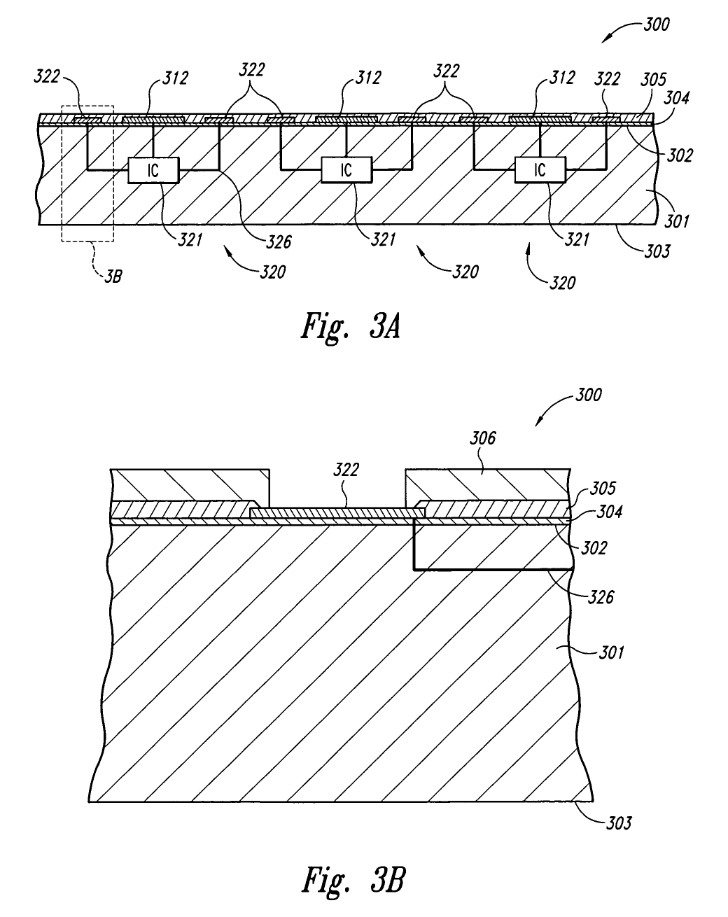

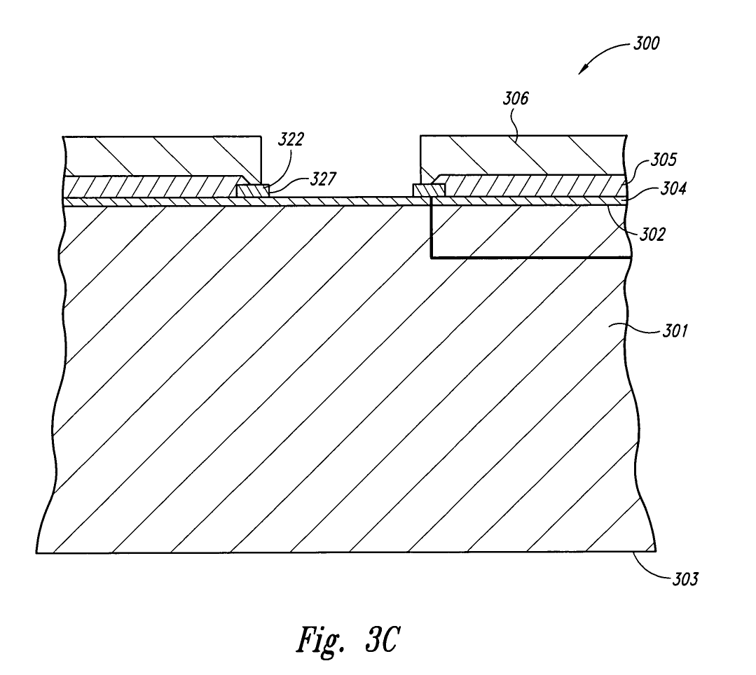

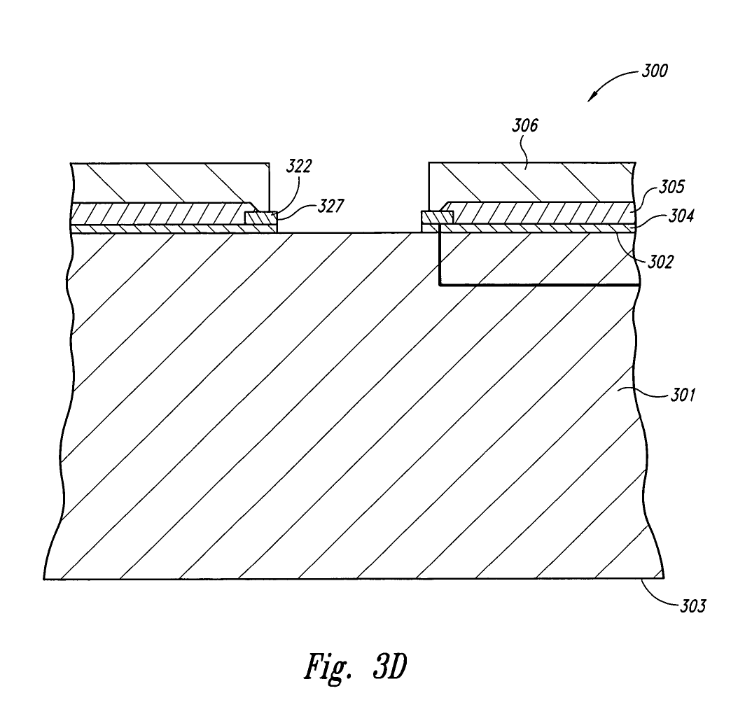

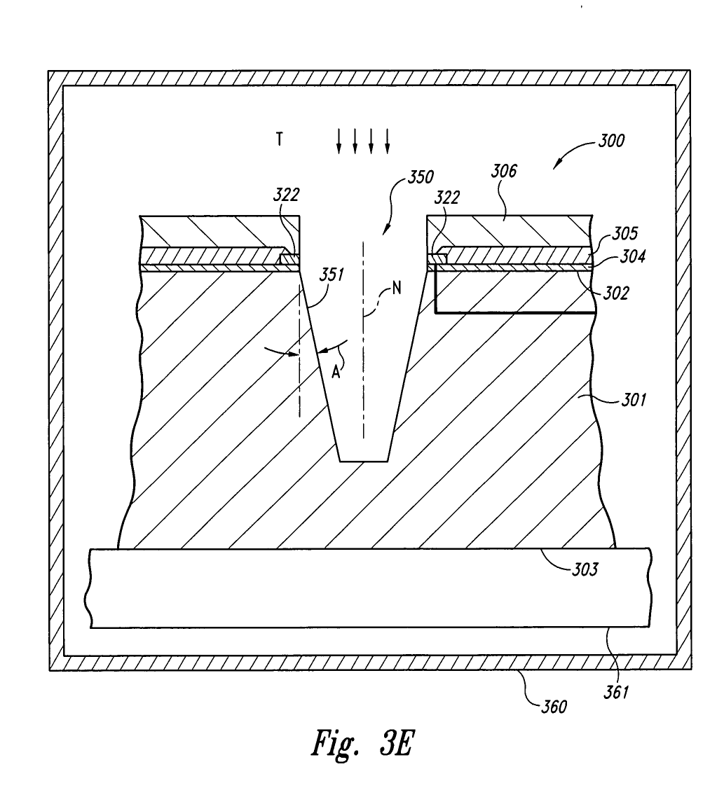

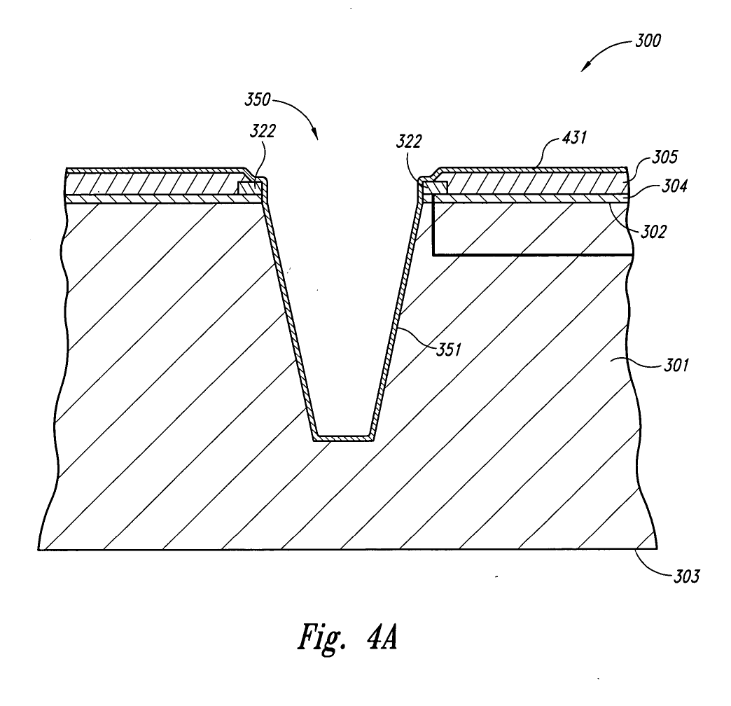

FIG. 2 is a flow diagram illustrating a process 200 for forming a microelectronic device. The process can include forming an operable microelectronic feature in a substrate (process portion 201), and subsequently coupling the microelectronic feature to a bond site, e.g., a bond pad (process portion 202). Intermediate processes include forming a via in the substrate (process portion 203). The via can be formed in accordance with one or more of several further process parameters. For example, the via can be formed at cryogenic temperatures (process portion 204), and/or the angle of the via sidewalls can be controlled (process portion 205), and/or material can be removed to form the via in a generally continuous process (process portion 206). A conductive material can then be disposed in the via and coupled to the bond site (process portion 208) to provide electrical communication between the microelectronic feature and devices external to the substrate. Further details of the foregoing process steps and the structures formed by executing those steps are described below with reference to FIGS. 3-5.

FIG. 3A is a side cross-sectional view of a portion of an imager workpiece 300 at an initial stage before the interconnects have been formed. The workpiece 300 can include a substrate 301 with a plurality of imaging dies 320 formed in and/or on the substrate 301. The substrate 301 has a first side or surface 302 and a second side or surface 303. The substrate 301 is generally a semiconductor wafer, and the imaging dies 320 are arranged in a die pattern on the wafer. Individual dies 320 can include integrated circuitry 321, a plurality of terminals or bond sites 322 (e.g., bond-pads) electrically coupled to the integrated circuitry 321, and an image sensor 312. The image sensors 312 can be CMOS image sensors or CCD image sensors for capturing pictures or other images in the visible spectrum. In other embodiments, the image sensors 312 can detect radiation in other spectrums (e.g., IR or UV ranges). The bond sites 322 shown in FIG. 3A are external features at the first side 302 of the substrate 301. In other embodiments, however, the bond sites 322 can be internal features that are embedded at an intermediate depth within the substrate 301.

FIG. 3B is a side cross-sectional view of the area 3B shown in FIG. 3A. In previous processing steps, a first dielectric layer 304 was applied to the first side 302 of the substrate 301, and a second dielectric layer 305 was applied over the first dielectric layer 304. The second dielectric layer 305 was then patterned and etched to expose the bond site 322. The dielectric layers 304 and 305 can be formed from a polyimide material or other nonconductive materials. For example, the first dielectric layer 304 and/or one or more of the subsequent dielectric layers can include parylene, a low temperature chemical vapor deposition (CVD) material such as tetraethylorthosilicate (TEOS), silicon nitride (Si₃N₄), silicon oxide (SiO₂), and/or other suitable materials. The foregoing list of dielectric materials is not exhaustive. The dielectric layers 304 and 305 may be but need not be composed of the same material. One or both of the layers 304 and 305 may be omitted and/or additional layers may be included in other embodiments.

After depositing the second dielectric layer 305, a mask 306 is applied over the second dielectric layer 305 and patterned as shown in FIG. 3B. The mask 306 can be a layer of resist that is patterned according to the arrangement of bond sites 322 on the substrate 301. Accordingly, the mask 306 can have an opening over each bond site 322.

As shown in FIG. 3C, a hole or aperture 327 has been formed through the second dielectric layer 305. The hole 327 can be formed using a wet etching process that selectively removes material from the bond site 322 but not the first dielectric layer 304. The first dielectric layer 304 can accordingly act as an etch-stop. In embodiments where the bond site 322 includes more than one type of metal, the etching process can be repeated until the hole 327 extends through the bond site 322.

Referring to FIG. 3D, the first dielectric layer 304 directly beneath the bond site 322 is etched to expose at least a portion of the substrate 301. The etching process for the first dielectric layer 304 can be different than the etching process for the bond site 322 to account for the different compositions of these structures. For example, the dielectric etching process can selectively remove material from the first dielectric layer 304 at a higher etch rate than from either the bond site 322 or the substrate 301. The dielectric etching process accordingly does not significantly alter the general structure of the bond site 322 or the substrate 301. In an alternative embodiment, the hole 327 can be etched through both the bond site 322 and the first dielectric layer 304 using a single etching process.

FIG. 3E illustrates a process for forming a via 350 in the substrate 301. The substrate 301 can be positioned in a plasma chamber 360 (shown schematically in FIG. 3E), where it can be supported on a cold chuck 361. The cold chuck 361 can control a temperature T in the chamber 360 and, more specifically, the temperature of, or at least proximate to, the substrate 301. The via 350 can then be formed in the substrate 301 using a plasma process, e.g., a deep reactive ion etching process. In a particular embodiment, the temperature T within the chamber 360 is controlled to cryogenic temperatures. For example, the temperature can be controlled to be from about −100° C. to about −130° C. (173K to 143K). In other embodiments, the temperature may be controlled to other levels, for example, levels at or above 71K (the temperature at which nitrogen liquifies).

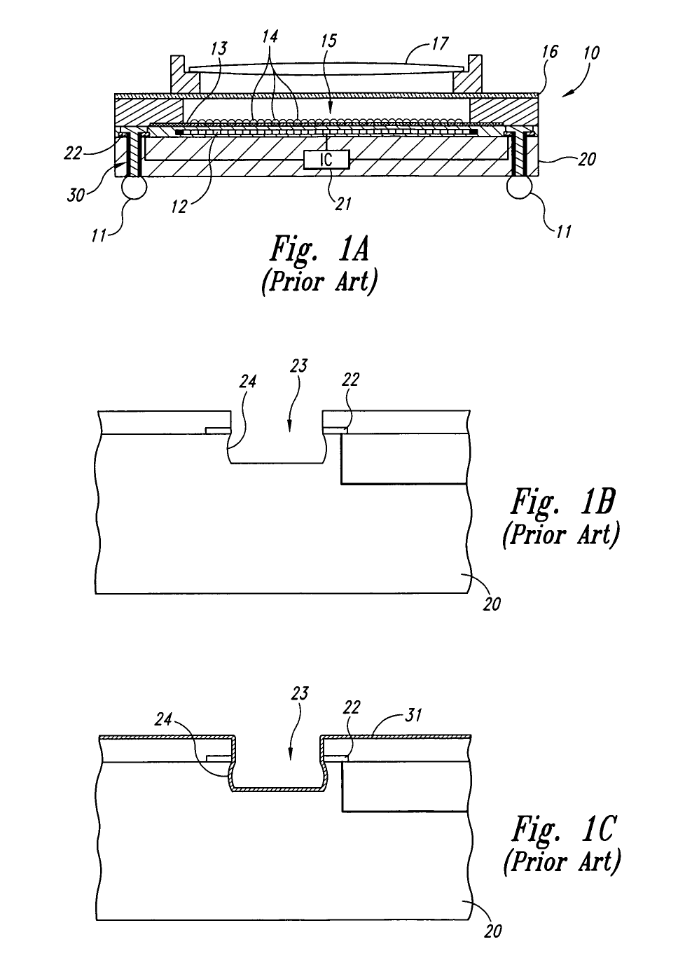

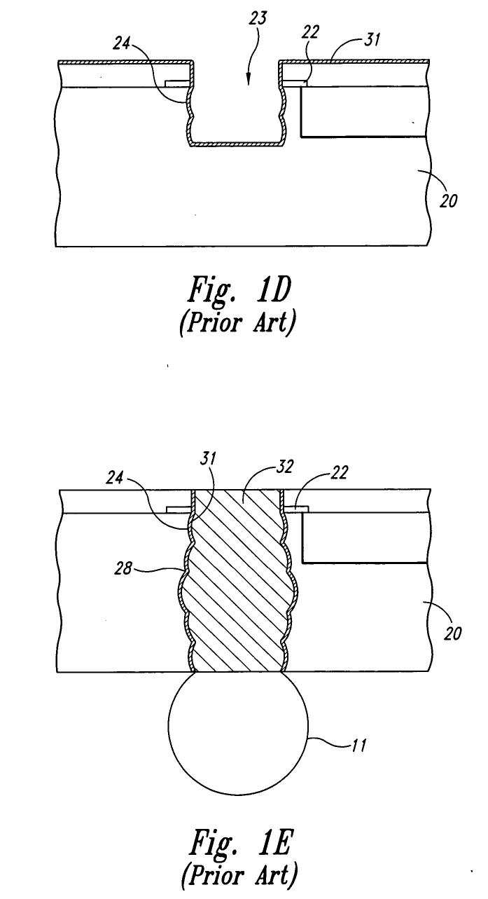

The low temperature at which the reactive ion etching process is performed can have several beneficial effects. One such effect is that the overall reaction rate between the plasma and the substrate material slows down. Because the plasma inherently has a higher removal rate for material located at the bottom of the via 350 than for material located at the sides of the via 350, the reduction in process rate can stop or nearly stop the plasma from removing material in a lateral direction (e.g., transverse to an axis N extending generally normal to the first surface 302). An advantage of this arrangement is that the sidewall 351 of the via 350 can have a generally smooth, continuous contour, and need not have the scalloped contour described above with reference to FIG. 1E. For example, the contour of the sidewall 351 can be described by a constant or monotonic function (e.g., a straight or curved non-oscillatory line). As a result, the tendency for stress concentrations to form in the sidewall 351 (and/or in materials positioned adjacent to the sidewall 351) can be significantly reduced and/or eliminated. Furthermore, the tendency for initially formed portions of the sidewall 351 to shadow other portions, or to otherwise interfere with processes performed on subsequently formed portions of the sidewall 351, can also be reduced and/or eliminated. Still another advantage of this process is that it can be simpler to implement than a process that requires intermittently removing material from the substrate and then passivating the exposed surface of the substrate in the via 350. Instead, the material can be removed from the via 350 in a continuous or at least approximately continuous process, which can reduce the amount of time required to form the via and therefore the overall cost of forming the via.

The precursor gas selected for the plasma process described above with reference to FIG. 3E can be selected from a variety of suitable compositions, and can be selected to depend upon factors that include the composition of the substrate 301 and/or the characteristics of the via 350 formed in the substrate 301. For example, the precursor gas can include SF₆ which, when exposed to oxygen, can form SlOₓF_{y}. In other embodiments, the precursor gas can include other flourine-based compositions, or compositions that include reactive constituents other than fluorine.

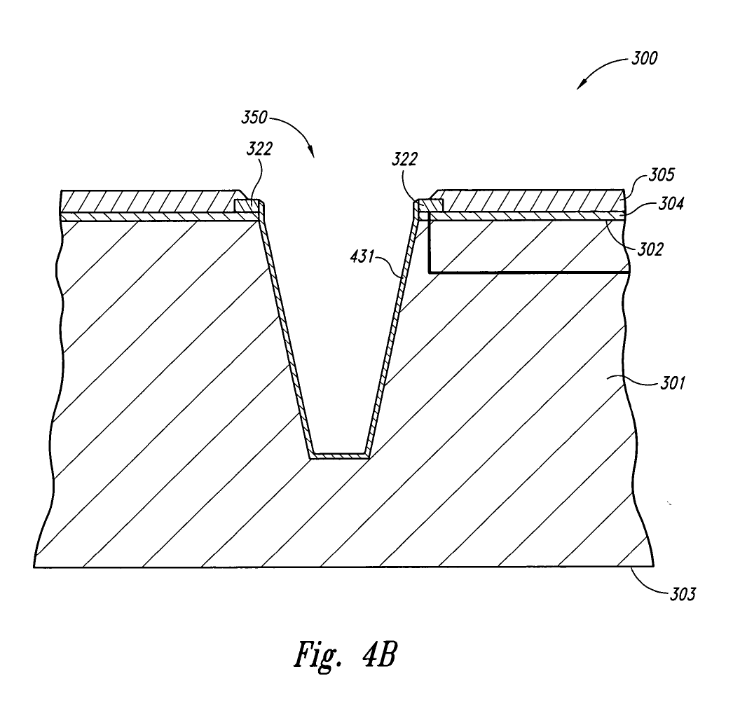

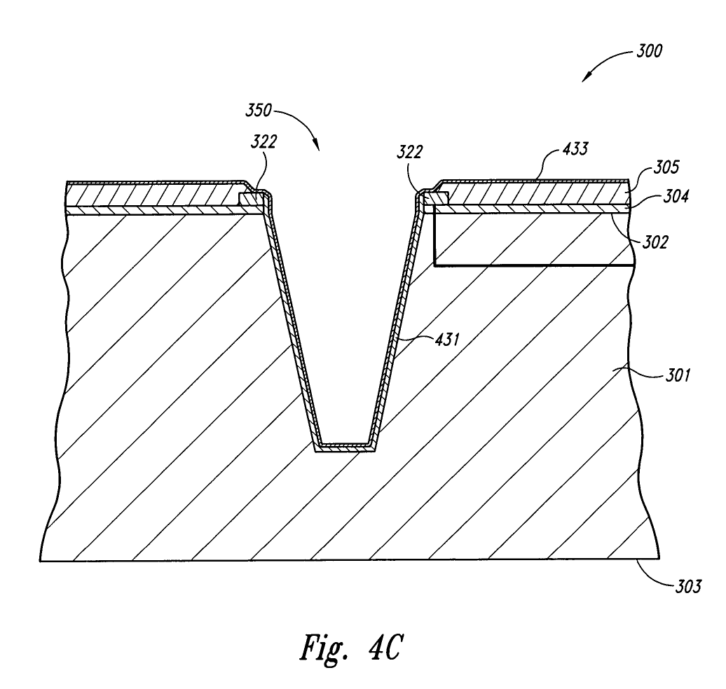

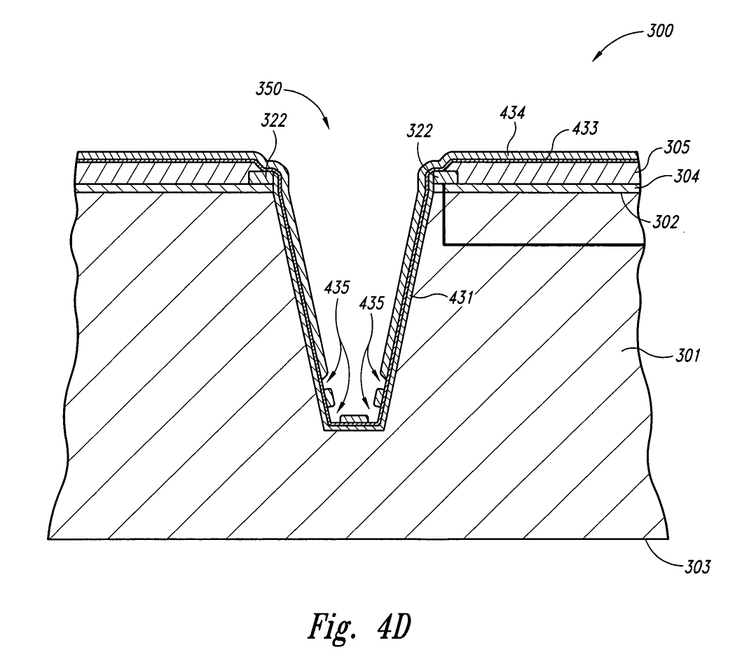

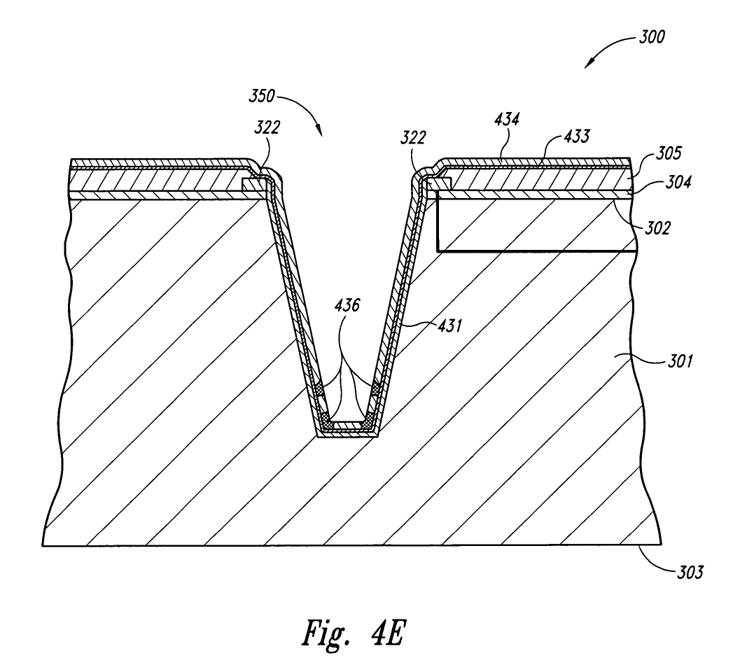

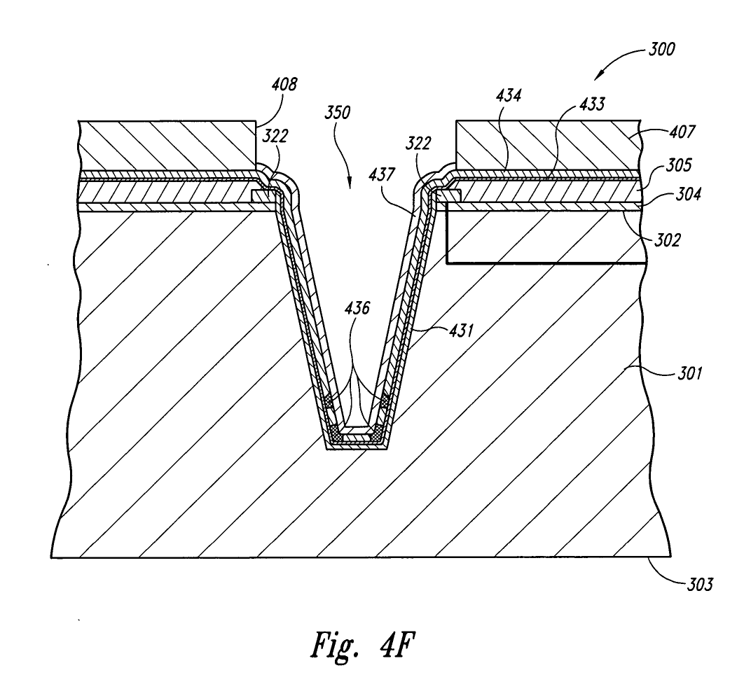

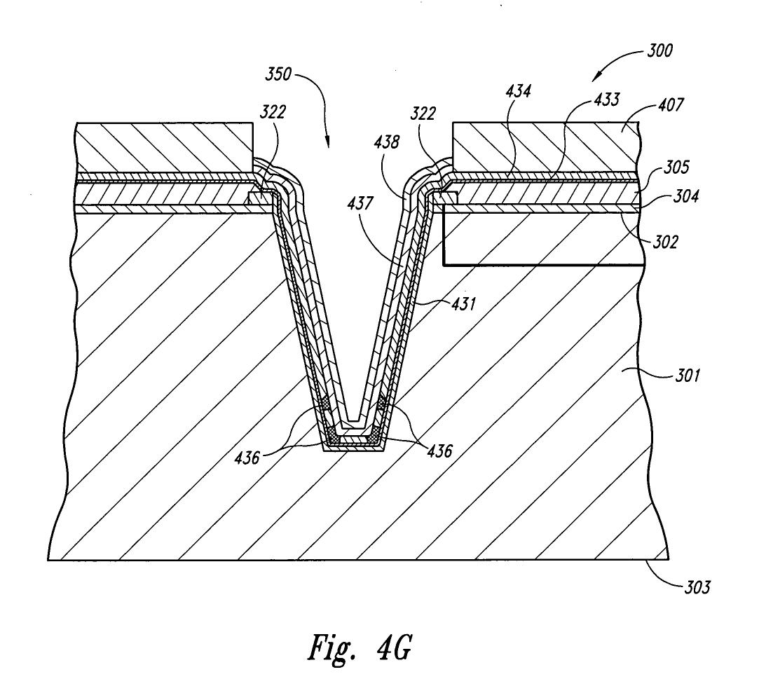

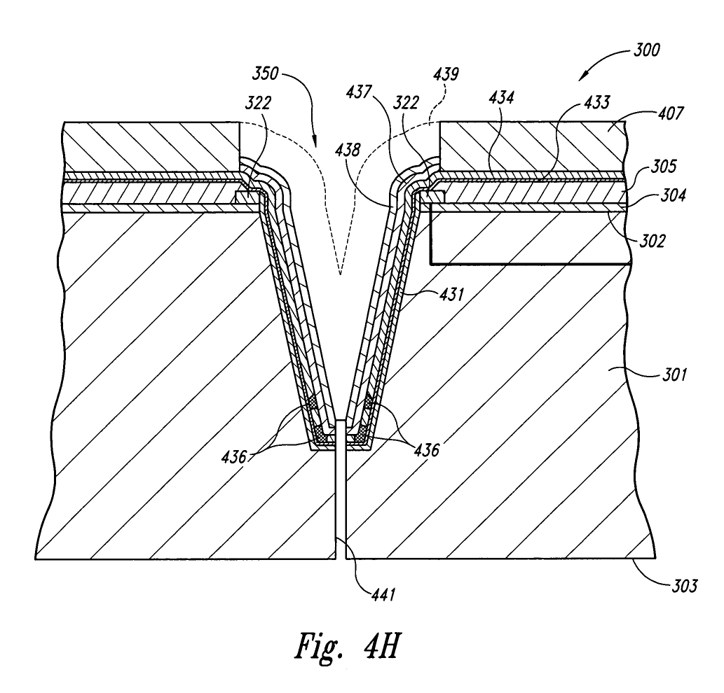

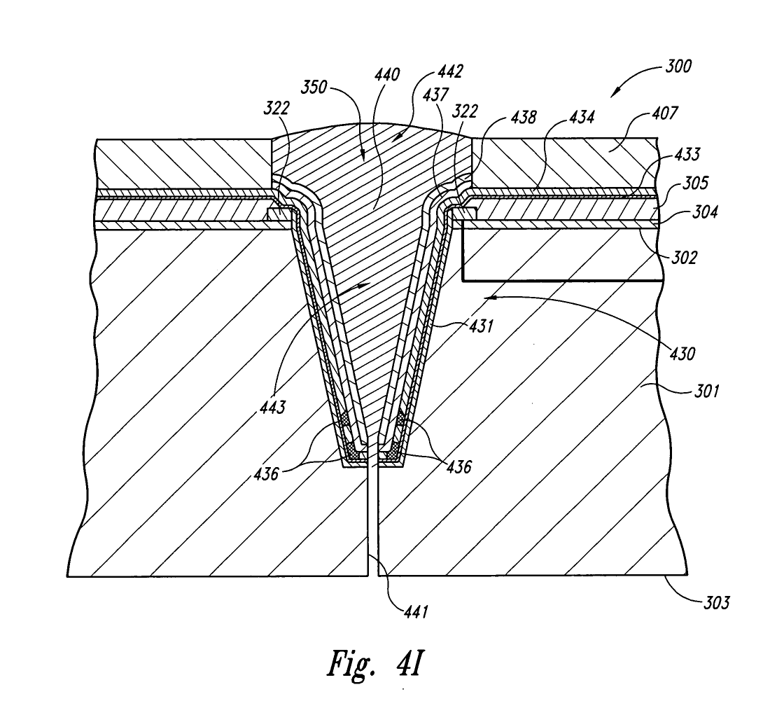

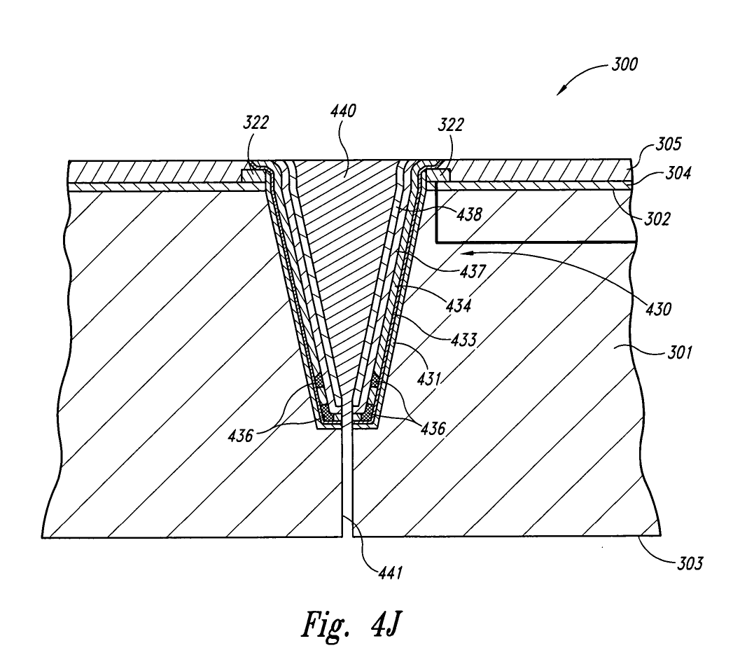

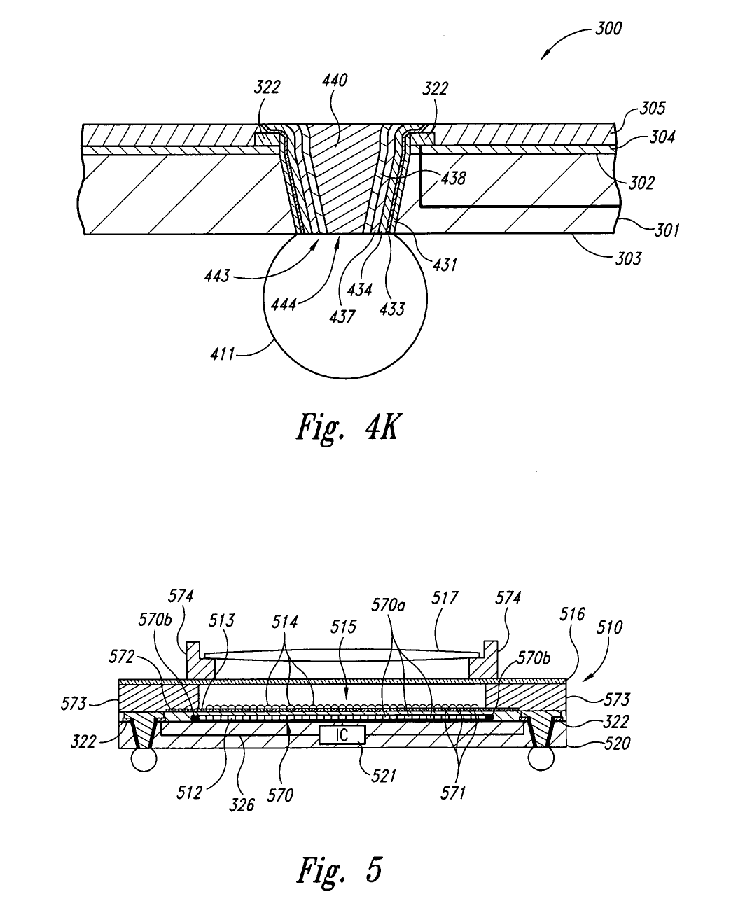

The size and shape of the via 350 can vary depending on the particular application. For example, the via 350 can have an aspect ratio of about 1:1 or greater in some embodiments. The via 350 can extend by a distance of at least 150 microns from the first surface 302. In any of the foregoing embodiments, the orientation of the sidewall 351 can be controlled by controlling one or more of the foregoing process parameters. For example, the overall shape of the via 350 can be tapered so that the sidewalls 351 form an angle A with respect to the normal axis N. The value of angle A can be from about 0° to about 5°, and in a particular embodiment, about 3°. The value of the angle A is exaggerated in FIG. 3E for purposes of illustration. The value of angle A can be controlled by controlling the temperature and/or oxygen concentration within the chamber 360. For example, at lower temperatures and/or lower oxygen concentrations, the angle A will tend toward zero degrees. One advantage of a non-zero degree sidewall angle is that it can reduce the likelihood for shadowing in subsequent processes. Another advantage is that the value of the sidewall angle A can determine what processes are used to dispose subsequent dielectric layers. For example, at high sidewall angles, relatively cheap processes, e.g., low silane oxide processes, can be used to form the dielectric layer. Further details of the dielectric materials and associated processes are described below with reference to FIG. 4A.

Referring next to FIG. 4A, a third dielectric layer 431 is deposited onto the workpiece 300 to line the sidewalls of the via 350 within the substrate 301. The third dielectric layer 431 electrically insulates components in the substrate 301 from an interconnect that is subsequently formed in the via 350, as described in greater detail below. In one embodiment, the third dielectric layer 431 can be an aluminum-rich oxide material applied using a pulsed layer deposition process or another suitable low temperature CVD oxide. In another embodiment, the third dielectric layer 431 can include a silane-based oxide material, e.g., a low silane oxide. A low silane oxide process can be particularly suitable when the sidewall angle of the via 350 is greater than zero degrees. This process is compatible with the low temperature at which the via 350 is formed. In still further embodiments, the third dielectric layer 431 can include other suitable dielectric materials. Referring to FIG. 4B, a suitable etching process (e.g., a spacer etch) is used to remove the third dielectric layer 431 from at least a portion of the bond site 322.

Referring to FIG. 4C, a barrier layer 433 is then deposited onto the workpiece 300 over the third dielectric layer 431 so as to be in electrical contact with the bond site 322. The barrier layer 433 generally covers the second dielectric layer 305 and the bond site 322 in addition to the third dielectric layer 431. In one embodiment, for example, the barrier layer 433 is a layer of tantalum that is deposited onto the workpiece 300 using physical vapor deposition (PVD). The thickness of the barrier layer 433 is about 150 Angstroms. In other embodiments, the barrier layer 433 may be deposited onto the workpiece 300 using other vapor deposition processes, such as CVD, and/or may have a different thickness. The composition of the barrier layer 433 is not limited to tantalum, but rather may be composed of tungsten or other suitable materials.

Referring next to FIG. 4D, a seed layer 434 is deposited onto the barrier layer 433. The seed layer 434 can be deposited using vapor deposition techniques, such as PVD, CVD, atomic layer deposition, and/or plating. The seed layer 434 can be composed of copper or other suitable materials. The thickness of the seed layer 434 may be about 2000 Angstroms, but could be more or less depending upon the depth and aspect ratio of the via 350. In several embodiments, the seed layer 434 may not uniformly cover the barrier layer 433 such that the seed layer 434 has voids 435 within the via 350. This can cause non-uniform electroplating in the via 350 and across the workpiece 300. When the seed layer 434 is deficient, it is preferably enhanced using a process that fills voids or noncontinuous regions of the seed layer 434 to form a more uniform seed layer. Referring to FIG. 4E, for example, voids 435 and/or noncontinuous regions of the seed layer 434 have been filled with additional material 436, such as copper or another suitable material. One suitable seed layer enhancement process is described in U.S. Pat. No. 6,197,181, which is incorporated by reference.

Referring next to FIG. 4F, a resist layer 407 is deposited onto the seed layer 434 and patterned to have an opening 408 over the bond site 322 and corresponding via 350. A first conductive layer 437 is then deposited onto the exposed portions of the seed layer 434 in the via 350. The first conductive layer 437 can include copper that is deposited onto the seed layer 434 in an electroless plating operation, or an electroplating operation, or by another suitable method. In the illustrated embodiment, the thickness of the first conductive layer 437 is about 1 micron. In other embodiments, the first conductive layer 437 may include other suitable materials and/or have a different thickness.

Referring to FIG. 4G, a second conductive layer 438 is deposited onto the first conductive layer 437 in the via 350. The second conductive layer 438 can include a wetting agent that facilitates depositing subsequent materials into the via 350. The second conductive layer 438 can include nickel that is deposited onto the first conductive layer 437 using an electroless or electrolytic plating process. In the illustrated embodiment, the thickness of the second conductive layer 438 is approximately 3-5 microns. In other embodiments, the via 350 may be coated with other suitable materials using other methods, and/or the via 350 can have a different thickness.

Referring next to FIG. 4H, a vent hole 441 is formed in the substrate 301 extending from a bottom portion of the via to the second side 303 of the substrate 301. The vent hole 441 can be formed using a laser to cut through the substrate 301 from the second side 303 to the bottom of the via 350. The laser can be aligned with the via 350 and/or the corresponding bond site 322 using scanning/alignment systems known in the art. A suitable laser is the Xise200, commercially available from Xsil Ltd. of Dublin, Ireland. After forming the vent hole 441, it is generally cleaned to remove ablated byproducts (i.e., slag) and/or other undesirable byproducts resulting from the laser. For example, the vent hole 441 can be cleaned using a suitable cleaning agent, such as 6% tetramethylammonium hydroxide (TMAH): propylene glycol. In other embodiments, the vent hole 441 may not be cleaned. In alternative embodiments, the vent hole 441 can be a different size or shape, and may be formed using an etching process (e.g., a dry etch and/or a wet etch), a mechanical drilling process, a dicing or laser slot, or another suitable method.

In several embodiments, a temporary protective filling or coating 439 (shown in broken lines) can be deposited into the via 350 before forming the vent hole 441. The protective filling 439 can be a photoresist, a polymer, water, a solidified liquid or gas, or another suitable material. The protective filling 439 protects the sidewalls of the via 350 from slag produced during the laser drilling process. The slag can negatively affect the plating of nickel onto the seed layer and/or the wetting of a conductive fill material in the via 350. The protective filling 439 can be removed after forming the vent hole 441.

Referring next to FIG. 4J, a conductive fill material 440 is deposited into the via 350 to form an interconnect 430. The interconnect 430 has a first end 442 proximate to the bond site 322 and a second end 443 at the bottom of the via 350. The fill material 440 can include Cu, Ni, Co, Ag, Au, solder, or other suitable materials or alloys of materials having the desired conductivity. The conductive fill material 440 can be deposited into the via 350 using plating processes, solder wave processes, screen printing processes, reflow processes, vapor deposition processes, or other suitable, techniques. The plating processes, for example, can be electroless plating processes or electroplating processes. In other embodiments, the conductive fill material 440 (and/or other materials disposed in the via 350) can be disposed in a supercritical fluid environment as described in pending U.S. application Ser. No. ______ (Attorney Docket No. 108298816US), titled “CONDUCTIVE INTERCONNECT STRUCTURES AND FORMATION METHODS USING SUPERCRITICAL FLUIDS,” filed concurrently herewith and incorporated herein by reference.

The resist layer 407 can then be removed from the substrate 301 (as shown in FIG. 4J) and a suitable etching process is used to remove the remaining portions of the seed layer 434 and barrier layer 433 on the first side 302 of the substrate 301. The first side 302 of the substrate 301 can be planarized using grinding, chemical mechanical planarization (CMP), and/or other suitable processes. The via 350 can initially be a blind via that can be made to extend entirely through the substrate by a back grinding process, as described in greater detail below with reference to FIG. 4K.

FIG. 4K illustrates the substrate 301 after material has been removed from the second surface 303 to expose the second end 433 of the interconnect structure 430. Accordingly, the second end 443 of the interconnect structure 430 can form a second bond site 444 to which the solder ball 411 can be attached for coupling the workpiece 301 to external devices.

FIG. 5 is a partially schematic illustration of a finished imaging device 510 configured in accordance with an embodiment of the invention. The imaging device 510 can include a die 520 having an integrated circuit 521 coupled to an image sensor 512, which can in turn include an array of pixels 570 arranged in a focal plane. In the illustrated embodiment, for example, the image sensor 512 can include a plurality of active pixels 570a arranged in a desired pattern, and at least one dark current pixel 570b located at a perimeter portion of the image sensor 512 to account for extraneous signals in the die 510 that might otherwise be attributed to a sensed image. In other embodiments, the arrangement of pixels 570 may be different.

A color filter array (CFA) 513 is positioned over the active pixels 570a of the sensor 512. The CFA 513 has individual filters or filter elements 571 configured to allow the wavelengths of light corresponding to selected colors (e.g., red, green, or blue) to pass to each pixel 570 of the image sensor 512. In the illustrated embodiment, for example, the CFA 513 is based on the RGB color model, and includes red filters, green filters, and blue filters arranged in a desired pattern over the corresponding active pixels 570a. The CFA 513 can further include a residual blue section 572 that extends outwardly from a perimeter portion of the image sensor 512. The residual blue section 572 helps prevent back reflection from the various components within the die 510.

The imaging device 510 can further include a plurality of microlenses 514 arranged in a microlens array 515 over the CFA 513. The microlenses 514 are used to focus light onto the initial charge accumulation regions of the image sensor pixels 513. Standoffs 573 are positioned adjacent to the microlens array 515 to support a transmissive element 516. The transmissive element 516 (which can include glass) is positioned to protect the microlens array 515 and other features of the die 520 from contamination. Lens standoffs 574 can be mounted to the transmissive element 516 to support a device lens 517. The device lens 517 is positioned a selected distance away from the microlens array 515 to focus light onto the microlens array 515 and ultimately onto the image sensor 512.

From the foregoing, it will be appreciated that specific embodiments of the invention have been described herein for purposes of illustration, but that various modifications may be made without deviating from the invention. For example, while aspects of the invention have been described in the context of image sensor devices, these aspects may be applied to other devices as well. In particular embodiments, aspects of the invention have been described in the context of integrated circuit devices coupled to interconnect structures formed in accordance with particular methods. In other embodiments, the interconnect structures can be coupled to other microelectronic features, for example, capacitors or conductive lines. Aspects of the invention described in the context of particular embodiments may be combined or eliminated in other embodiments. Further, while advantages associated with certain embodiments of the invention have been described in the context of those embodiments, other embodiments may also exhibit such advantages, and not all embodiments need necessarily exhibit such advantages to fall within the scope of the invention. Accordingly, the invention is not limited except as by the appended claims.

1-12. (canceled)

13. A method for forming a microelectronic device, comprising:
forming an operable microelectronic feature in a substrate, the substrate having a first surface and a second surface facing away from the first surface;
forming a via in the substrate at a process temperature of less than 173K, the via extending into the substrate from the first surface;
disposing a conductive material in the via, the conductive material being in electrical communication with a bond site of the substrate; and
coupling the microelectronic feature to the bond site.

14. The method of claim 13 wherein the bond site is a first bond site, and wherein the method further comprises:
removing material from the second surface of the substrate to expose the conductive material in the via; and
connecting the conductive material in the via to a second bond site at the second surface of the substrate.

15. The method of claim 13 wherein forming a via includes forming a via at a temperature above about 71K.

16. The method of claim 13 wherein forming a via includes forming a via at a temperature of from about 143K to about 173K.

17. The method of claim 13 wherein forming a via includes forming a via using a deep reactive ion etch process.

18. The method of claim 13 wherein forming the via includes removing material from the microfeature workpiece in a generally continuous manner.

19. The method of claim 13 wherein forming a via includes removing material in a single, generally continuous process without intermittently depositing material in the via.

20. The method of claim 13 wherein forming a via includes forming a via by exposing the microfeature workpiece to a plasma.

21. The method of claim 13 wherein forming a via includes forming a via using a fluorine plasma process.

22. The method of claim 13, further comprising passivating the sidewalls of the via.

23. The method of claim 13 wherein forming the via includes removing material from the microfeature workpiece in a direction generally normal to the first surface at a first rate, and not removing material in a direction generally transverse to the first surface, or removing material in a direction generally transverse to the first surface at as second rate less than the first rate.

24. The method of claim 13, further comprising controlling an angle of the via sidewalls relative to an axis extending through the via generally normal to the first and second surfaces

25. A method for forming a microelectronic device, comprising:
forming an operable microelectronic feature in a substrate, the substrate having a first surface and a second surface facing away from the first surface;
forming a via in the substrate, the via having sidewalls extending from the first surface;
controlling an angle of the via sidewalls relative to an axis extending through the via generally normal to the first and second surfaces;
disposing a conductive material in the via, the conductive material being in electrical communication with a bond site of the substrate; and
coupling the microelectronic feature to the bond site.

26. The method of claim 25 wherein the bond site is a first bond site, and wherein the method further comprises:
removing material from the second surface of the substrate to expose the conductive material in the via; and
connecting the conductive material in the via to a second bond site at the second surface of the substrate.

27. The method of claim 25 wherein forming a via includes forming a via in a cryogenic process.

28. The method of claim 25 wherein forming a via includes forming a via at a temperature below 173K.

29. The method of claim 25 wherein forming the via includes removing material from the microfeature workpiece in a single, generally continuous process.

30. The method of claim 25 wherein controlling an angle of the via sidewalls includes controlling at least one of a temperature and an oxygen concentration of an environment in which the via is formed.

31. The method of claim 25 wherein controlling an angle of the via sidewalls includes controlling both a temperature and an oxygen concentration of an environment in which the via is formed.

32. The method of claim 25 wherein forming the via includes exposing the microfeature workpiece to SF₆.

33. The method of claim 25 wherein disposing a conductive material includes disposing a conductive barrier layer and a conductive fill material.

34. A method for forming a microelectronic device, comprising:
forming a microelectronic feature in a substrate, the substrate having a first surface and a second surface facing away from the first surface;
removing material from the substrate in a single, generally continuous process to form a via in the substrate extending into the substrate from the first surface;
disposing a conductive material in the via, the conductive material being in electrical communication with a bond site of the substrate; and
coupling the microelectronic feature to the bond site.

35. The method of claim 34 wherein the bond site is a first bond site, and wherein the method further comprises:
removing material from the second surface of the substrate to expose the conductive material in the via; and
connecting the conductive material in the via to a second bond site at the second surface of the substrate.

36. The method of claim 34 wherein forming the via includes forming the via at a process temperature of less than 173K.

37. The method of claim 34, further comprising controlling an angle of via sidewalls relative to an axis extending through the via generally normal to the first and second surfaces.

38. The method of claim 34, further comprising forming a dielectric layer in the via before disposing the conductive material in the via.

39. The method of claim 34, further comprising controlling an angle at which sidewalls of the via are inclined relative to an axis extending generally normal to the first surface of the substrate.
